(19) United States
(12) Patent Application Publication
(10) Pub. No.: US 2009/0283124 A1
(43) Pub. Date: Nov. 19, 2009

(54) METHOD AND APPARATUS FOR ELECTRIC POWER SUPPLY USING THERMOELECTRIC CONVERSION

(75) Inventor: Kwang-youn Seo, Suwon-si (KR)

Correspondence Address: STEIN MCEWEN, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/271,209

(22) Filed: Nov. 14, 2008

(30) Foreign Application Priority Data
May 13, 2008 (KR) 2008-44016

(51) Int. Cl. H01L 35/34; H01L 35/30

(52) U.S. Cl. 136/201; 136/205

(57) ABSTRACT

An electric power supply method and apparatus using thermoelectric conversion include an electric power supply apparatus that converts thermal energy, which is generated from a plurality of thermal sources of a device when the device operates using electric power stored in a first power source unit that supplies external power to the device, into electricity; stores the obtained electricity in a second power source unit; and supplies the stored electricity to the device. Accordingly, it is possible to recycle thermal energy generated when the device operates, thereby minimizing consumption of electric power in the device.

### CROSS-REFERENCE TO RELATED APPLICATION

This application claims the benefit of Korean Patent Application No. 2008-44016, filed on May 13, 2008, in the Korean Intellectual Property Office, the disclosure of which is incorporated herein in its entirety by reference.

### BACKGROUND OF THE INVENTION

1. Field of the Invention

Aspects of the present invention relate to an apparatus and method for electric power supply using thermoelectric conversion, and more particularly, to a method and apparatus for recycling thermal energy generated in a device by converting the thermal energy into electrical energy through thermoelectric conversion.

2. Description of the Related Art

Physical phenomena, such as the Seebeck effect or the Peltier effect, which indicate that the flow of heat and electric current influence each other, are referred to as thermoelectric effects. These thermoelectric effects occur in circuits manufactured by uniting metals or semiconductors having different thermoelectric properties. Also, conversion from thermal energy to electrical energy or vice versa by using such a circuit is referred to as thermoelectric conversion. Thermal energy is converted into electrical energy according to the Seebeck effect or electric energy is converted into thermal energy according to the Peltier effect.

Use of thermoelectric conversion makes it possible to generate electric power from the flow of heat or to generate an endothermic or exothermic reaction from current. The thermoelectric conversion has been considered as a high-efficient energy utilization technique for a number of reasons, such as the fact that it is possible to prevent excessive amounts of waste products from being output during energy conversion since the thermoelectric conversion is a direct conversion of energy from one form to another, and it is also possible to provide convenient management and maintenance of a device utilizing the phenomenon since a typical electricity generator, such as a motor or a turbine, which have physically moving parts, is not necessary.

A module performing thermoelectric conversion using the Seebeck effect is referred to as a ThermoElectric Generator (TEG) or a thermogenerator. When one side surface of the TEG is heated and the other side surface thereof is cooled, thermal energy flows from the heated side surface to the cooled side surface, and the TEG converts the thermal energy into current. For example, if one side surface of the TEG is attached to a central processing unit (CPU) of a computer and the other side surface of the TEG is attached to a heat sink, such as a cooling fan, thermal energy flows from the CPU to the heat sink and the TEG converts the thermal energy into current.

In particular, as CPU operating clock frequencies have recently increased in order to improve computer performance, not only the amount of heat generated by a computer but also electric power consumption thereof have increased. Accordingly, there is a need for development of an electric power supply method and apparatus capable of reducing electric power consumption by recycling thermal energy generated by an electronic device such as a computer.

### SUMMARY OF THE INVENTION

Aspects of the present invention provide an electric power supply method and apparatus capable of minimizing consumption of electric power in a device by efficiently recycling thermal energy generated by at least one unit that is included in the device.

According to an aspect of the present invention, an electric power supply apparatus includes a thermoelectric conversion unit to convert heat generated from at least one thermal source of a device into electricity when the device operates using electricity from a first power source unit; a charging unit to charge the electricity obtained by the thermoelectric conversion unit in a second power source unit; and a power control unit to control the first and second power source units in order to supply the electricity of the first or second power source unit to the device based on operational modes of the device.

According to an aspect of the present invention, if the device is switched to a standby mode, the power control unit may control the first and second power source units in order to supply the electricity of the first or the second power source unit to the device.

According to an aspect of the present invention, if the device is switched to the standby mode and the amount of the electricity in the second power source unit is equal to or greater than a predetermined value, the power control unit may control the first and second power source units in order to supply the electricity of the second power source unit to the device.

According to an aspect of the present invention, if the device is switched to the standby mode and the amount of the electricity in the second power source unit is less than a predetermined value, the power control unit may control the first and second power source units in order to supply the electricity of the first power source unit to the device.

According to an aspect of the present invention, the charging unit may include a blocking unit having a plurality of diodes respectively connected to a plurality of thermoelectric generators, the diodes blocking electricity generated by each of the thermoelectric generators from flowing towards the other thermoelectric generators; and an electric conversion unit to convert electricity having different power levels, which are generated by the respective thermoelectric generators, into electricity having the same voltage.

According to another aspect of the present invention, an electric power supply method includes, if a device operates using electricity from a first power source unit, converting heat generated from at least one thermal source of the device into electricity; storing the converted electricity in a second power source unit; and controlling the first and second power source units in order to supply the electricity of the first or second power source unit to the device based on operational modes of the device.

According to an aspect of the present invention, if the device is switched to a standby mode, the controlling of the first and second power source units may include controlling the first and second power source units in order to supply the electricity in the first or the second power source unit to the device.

According to an aspect of the present invention, if the device is switched to the standby mode and the amount of the electricity in the second power source unit is equal to or greater than a predetermined value, the controlling of the first and second power source units comprises controlling the first and second power source units in order to supply the electricity of the second power source unit to the device.

According to an aspect of the present invention, if the device is switched to the standby mode and the amount of the electricity in the second power source unit is less than a predetermined value, the controlling of the first and second power source units may include controlling the first and second power source units in order to supply the electricity of the first power source unit to the device.

According to another aspect of the present invention, a computer readable medium has recorded thereon a computer program for an electric power supply apparatus to execute the above method to supply electricity from a plurality of sources to a device.

According to another aspect of the present invention, an electronic apparatus having components that generate heat during operation thereof includes: a first electric power source to supply main electric power to the electronic apparatus to operate the electronic apparatus in a normal mode; a second electric power source to supply auxiliary electric power to the electronic apparatus in a standby mode, the auxiliary electric power being less than the main electric power; an electric power supply apparatus to recycle thermal energy of the heat generated by at least one of the components into electricity during the normal mode, charge the electricity to the second electric power source during the normal mode, and control the second electric power source to supply the charged electricity as the auxiliary electric power to the electronic apparatus during the standby mode.

According to another aspect of the present invention, a method of supplying electric power to an electronic apparatus having components that generate heat during operation thereof, including: supplying main electric power from a first electric power source to the electronic apparatus to operate the electronic apparatus in a normal mode; recycling thermal energy of the heat generated by at least one of the components into electricity during the normal mode; charging the electricity to the second electric power source during the normal mode; and controlling a second electric power source to supply the charged electricity as auxiliary electric power to the electronic apparatus during the standby mode, the auxiliary electric power being less than the main electric power.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the aspects, taken in conjunction with the accompanying drawings of which:

FIG. 1 is a block diagram of an electric power supply apparatus according to an aspect of the present invention;

FIG. 2 is a block diagram of a charging unit illustrated in FIG. 1;

FIG. 3 is a block diagram of a power control unit illustrated in FIG. 1;

FIG. 4 is a flowchart illustrating an electric power supply method according to an aspect of the present invention; and

FIG. 5 is a flowchart illustrating an electric power supply method according to another embodiment of the present invention.

### DETAILED DESCRIPTION OF THE EMBODIMENTS

Reference will now be made in detail to the aspects of the present invention, examples of which are illustrated in the accompanying drawings, wherein like reference numerals refer to the like elements throughout. The aspects are described below in order to explain the present invention by referring to the figures.

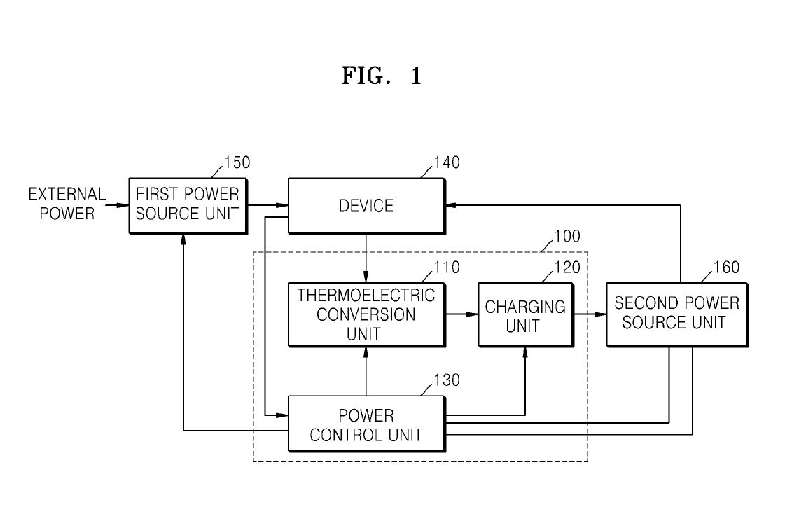

FIG. 1 is a block diagram of an electric power supply apparatus 100 (hereinafter referred to as “the apparatus 100”) according to an aspect of the present invention. Referring to FIG. 1, the apparatus 100 includes a thermoelectric conversion unit 110, a charging unit 120, and a power control unit 130.

The thermoelectric conversion unit 110 converts heat generated from at least one thermal source (not shown) of a device 140 into electricity. As described above, the Seebeck effect allows electricity to be obtained by converting thermal energy generated from such a thermal source into electrical energy (electricity or current). For example, a computer includes at least one chip, such as a central processing unit (CPU) and a graphics processing unit (GPU), which emits thermal energy (or heat). In this case, thermal energy may be converted into electrical energy by attaching a thermoelectric generator (TEG) to the at least one chip, to perform the thermoelectric conversion.

The device 140 may be a separate electronic device outside the apparatus 100 as illustrated in FIG. 1, or may be a circuit, such as a computer mother board, which is included in an electronic device together with the apparatus 100. The thermal source of the device 140 may be any portion of the device 140 that generates a designated amount of heat or that reaches a designated temperature for a designated amount of time.

While the device 140 operates using power obtained from a first power source unit 150, energy generated from the at least one thermal source of the device 140 is converted into electrical energy by the thermoelectric conversion unit 110. The first power source unit 150 is a device that supplies the device 140 with electric power, such as external electric power, needed to operate the device 140. The first power source unit 150 may be an inverter, e.g., an alternating current (AC)/direct current (DC) inverter that converts AC into DC. In other words, the first power source unit 150 may be an inverter to convert external electric power needed to operate the device 140 in a normal mode (i.e., when operating normally). In other aspects, the first power source 150 may be a rechargeable secondary battery.

The charging unit 120 charges the electricity, which is obtained or converted by the thermoelectric conversion unit 110, to a second power source unit 160. Thus, the thermoelectric conversion unit 110 converts heat generated from the at least one thermal source of the device 140 into electricity, and the charging unit 120 charges the second power source unit 160 with the electricity.

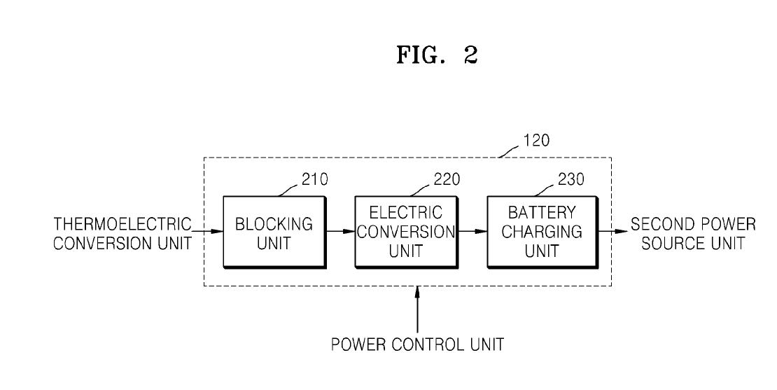

The second power source unit 160 is a device that can store electricity. The second power source unit 160 may be a secondary battery that converts electrical energy into chemical energy to store the electrical energy. The charging unit 120 will be described in greater detail with reference to FIG. 2.

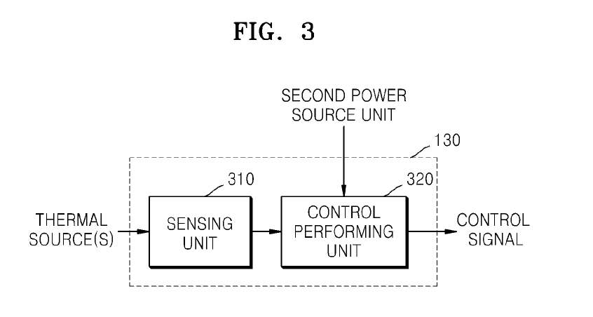

Additionally, the power control unit 130 controls the first power source unit 150, the thermoelectric conversion unit 110, the charging unit 120, and the second power source unit 160 in order to control conversion of the thermal energy into electricity, the charging and/or storing of the electricity, and supply of electricity of the first power source unit 150 and the second power source unit 160 to the device 140. The power control unit 130 will be described in greater detail with reference to FIG. 3.

FIG. 2 is a block diagram of the charging unit 120 illustrated in FIG. 1 according to an aspect of the present invention. Referring to FIG. 2, the charging unit 120 includes a blocking unit 210, an electric conversion unit 220, and a battery charging unit 230.

Referring to FIGS. 1 and 2, the blocking unit 210 ensures that electricity flows in only one direction when the thermoelectric conversion unit 110 outputs the electricity to be stored in the second power source unit 160. When the thermoelectric conversion unit 110 is converting thermal energy into electrical energy, heat generated from a thermal source of the device 140 may be irregular. For example, amount of heat generated from the thermal source of the device 140 may not be constant. Accordingly, the amount or power level of electricity from the thermoelectric conversion unit 110 may fluctuate, or otherwise, be irregular.

If the power level of electricity generated by the thermoelectric conversion unit 110 is too low to be charged in the second power source unit 160, the electricity may flow from the charging unit 120 to the thermoelectric conversion unit 110. Thus, the blocking unit 210 prevents the electricity from flowing from the charging unit 120 to the thermoelectric conversion unit 110 by using a unidirectional device, such as a diode, to ensure that electricity flows only in one direction. Further, when the thermoelectric conversion unit 110 converts heat generated from the thermal source of the device 140 into electricity by using a plurality of TEGs, the blocking unit 210 prevents electricity generated by a plurality of TEGs from flowing in an unwanted direction by using a plurality of diodes. By respectively connecting the diodes to the TEGs, it is possible to not only prevent electricity from flowing in unwanted directions, but to also prevent interference from occurring between electricity generated from the plurality of the TEGs when charging the second power source unit 160.

Referring back to FIG. 2, the electric conversion unit 220 converts electricity having different electric power levels (such as different voltages) that are generated by the plurality of TEGs to designated power levels, such as a single voltage. If the thermoelectric conversion unit 110 converts heat generated from the thermal source of the device 140 into electricity having different power levels by using the plurality of TEGs, the electric conversion unit 220 converts electricity of different power levels to electricity of designated power levels, such as a single power level or a single voltage, so that the second power source unit 160 can be charged with electricity. If the thermal sources of the device 140 emit different thermal energies and the TEGs generate electricity from the different thermal energies through thermoelectric conversion, electricity generated by the plurality of TEGs may have different electric power levels. When charging the second power source unit 160 with electricity having different electric power levels, the efficiency of the charging operation may be degraded.

It is assumed that electricity generated by the TEGs have different voltages. In this case, if the second power source unit 160 is charged with electricity having different voltages at the same time, the second power source unit 160 is not charged with electricity having lower voltages from among the electricity, and is instead, charged with only electricity having higher voltages from among the electricity, thereby causing inefficient charging. To solve this problem, the electric conversion unit 220 converts electricity having different voltages into electricity having the same voltage. Here, the same voltage is equal to or greater than a minimum voltage needed to charge the second power source unit 160 with the electricity.

The conversion of electricity having different voltages may be performed by storing electricity generated by the TEGs in different electric capacitors, and delivering only electricity having voltages equal to or greater than the minimum voltage, but matching a designated voltage, to the battery charging unit 230. In this case, it is possible to control the order of delivering electricity stored in the different electric capacitors so that they can be delivered to the battery charging unit 230 at different times. The battery charging unit 230 charges the second power source unit 160 with the electricity converted by the electric conversion unit 220.

Although FIG. 2 illustrates the charging unit 120 as including both the blocking unit 210 and the electric conversion unit 220, the charging unit 120 may include only one of them according to aspects of the present invention. In other words, the charging unit 120 may include only the blocking unit 210 and the battery charging unit 230, or only the electric conversion unit 220 and the battery charging unit 230 in various aspects of the present invention.

Referring back to FIG. 1, the power control unit 130 controls the first power source unit 150 and the second power source unit 160 in order to supply electricity from the first power source unit 150 or the second power source unit 160 to the device 140. The power control unit 130 controls the first power source unit 150 and the second power source unit 160 so that the electricity from the first or second power source unit 150 or 160 can be supplied to the device 140 according to operating modes of the device 140.

When the device 140 operates in a normal mode, the first power source unit 150 and the second power source unit 160 are controlled so that the electricity, for example, from an outside source that is converted by the first power source unit 150, can be supplied to the device 140. The normal mode refers to a mode in which the device 140 operates normally in order to perform its functions. For example, the normal mode may be an operating mode in which a television (TV) reproduces a broadcast signal, a digital versatile disc (DVD) player reads data from a DVD, or a computer processes data. When the device 140 operates in the normal mode, the second power source unit 160 is switched off so that the electricity in the second power source unit 160 cannot be supplied to the device 140, and the first power source unit 150 is switched on so that the electricity of the first power source unit 150 can be supplied to the device 140.

If the device 140 operates in a mode other than the normal mode, the first power source unit 150 and the second power source unit 160 are controlled so that the electricity in the second power source unit 160 can be supplied to the device 140. A mode other than the normal mode may be a standby mode. The standby mode refers to an operating mode in which the device 140 does not operate while still being connected to a power source. For example, the standby mode may be an operating mode in which an electronic device, such as the TV or the computer, does not operate while an electric power source cord thereof is inserted into an electric outlet.

In the standby mode, the amount of electric power consumed by the device 140 is small, i.e., approximately 1 to 3 W. Thus, in the standby mode, the first power source unit 150 and the second power source unit 160 are controlled so that the device 140 can obtain electric power to be consumed not from, for example, an external power source via the first power source unit 150, but from the second power source unit 160 that stores electricity that have been converted from thermal energy.

In the standby mode of the device 140, the first power source unit 150 is switched off so that the electricity from the first power source unit 150 cannot be supplied to the device 140, and the second power source unit 160 is switched on so that the electricity from the second power source unit 160 can be supplied to the device 140. The supply of electricity from the second power source unit 160 will be discussed in greater detail with reference to FIG. 3.

FIG. 3 is a block diagram of the power control unit 130 illustrated in FIG. 1 according to an aspect of the present invention. Referring to FIG. 3, the power control unit 130 includes a sensing unit 310 and a control performing unit 320.

The sensing unit 310 senses an operating mode of the device 140 of FIG. 1. That is, the sensing unit 310 senses whether the device 140 operates in the normal mode or the standby mode. The sensing unit 310 can also sense the temperatures of a plurality of thermal sources. If the amount of thermal energy generated from a thermal source is very small, for example, the amount of electricity obtained through thermoelectric conversion is also very small. Thus, the thermoelectric conversion unit 110 is to be controlled in order to select a thermal source, the temperature of which is equal to or greater than a predetermined temperature, and to selectively perform thermoelectric conversion with respect to the selected thermal source. To this end, the sensing unit 310 senses the temperatures of a plurality of thermal sources included in the device 140, and delivers or provides the sensing result to the control performing unit 320.

The control performing unit 320 controls the first power source unit 150 and the second power source unit 160 based on the sensing result received from the sensing unit 310. If the device 140 operates in the normal mode, the first power source unit 150 and the second power source unit 160 are controlled in order to supply electricity from the first power source unit 150 to the device 140. If the device 140 operates in the standby mode, the first power source unit 150 and the second power source unit 160 are controlled in order to supply electricity from the second power source unit 160 to the device 140.

Also, the control performing unit 320 can receive information regarding the amount of the electricity in the second power source unit 160, and control the first power source unit 150 and the second power source unit 160 based on the information. If the amount of the electricity in the second power source unit 160 is not enough to operate the device 140, the first power source unit 150 and the second power source unit 160 can be controlled in order to supply the electricity from the first power source unit 150 even if the device 140 operates in a mode other than the normal mode. In other words, the first power source unit 150 and the second power source unit 160 can be controlled in order to supply the electricity from the second power source unit 160 to the device 140 only when the device 140 operates in the standby mode and when the electricity in the second power source unit 160 is equal to or greater than a predetermined amount of electricity.

The control performing unit 320 also controls the thermoelectric conversion unit 110 and the charging unit 120. The thermoelectric conversion unit 110 is controlled to convert heat generated from at least one thermal source (not shown) of a device 140 into electricity, and the charging unit 120 is controlled to charge the electricity obtained or converted by the thermoelectric conversion unit 110 to the second power source unit 160.

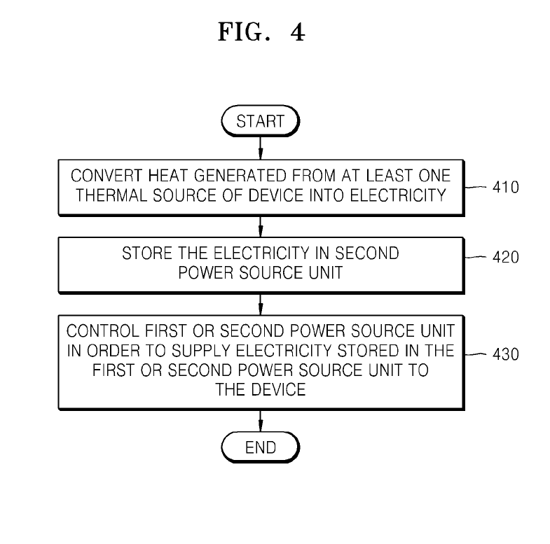

FIG. 4 is a flowchart illustrating an electric power supply method according to an aspect of the present invention. Referring to FIG. 4, in operation 410, an electric power supply apparatus (hereinafter referred to as “the apparatus”) converts heat generated from at least one thermal source of a device into electricity in order to operate the device by using electricity from a first power source unit. A thermoelectric generator (TEG) is used to convert thermal energy into electric energy. The first power source unit, for example, converts external electric power needed to operate the device into electricity, and supplies the electricity to the device. As described above, the first power source may be an AC/DC inverter.

Thermal energy is converted into electric energy by attaching at least one TEG to perform thermoelectric conversion to a thermal source of the device, such as a computer chip, which generates heat. That is, one end of the TEG is attached to a chip generating heat and the other end is attached to a heat sink cooling the chip. The TEG converts thermal energy flowing from the chip to the heat sink into electric energy.

In operation 420, the apparatus stores the electricity obtained through thermoelectric conversion in operation 410 in a second power source unit. The second power source unit is a device capable of storing electricity, e.g., a secondary battery that converts electric energy into chemical energy and stores the chemical energy. If in operation 410, heat generated from a plurality of thermal sources is converted into electricity via a plurality of TEGs, a diode is used in order to prevent electricity from flowing backward or to prevent electricity from interfering with one another. Also, it is possible to convert electricity having different power levels or voltages into electricity having the same power level or voltage, and store the converted electricity in the second power source unit.

In operation 430, the apparatus controls the first power source unit and the second power source unit in order to supply the device with either the electricity of the first power source unit or the electricity stored in the second power source unit in operation 420. In this case, the first power source unit may be switched on and the second power source unit may be switched off in order to supply only the electricity of the first power source unit to the device, or the first power source unit may be switched off and the second power source unit may be switched on in order to supply the electricity stored in the second power source unit to the device. It is sensed whether the device operates in the normal mode or the standby mode, and the first power source unit and the second power source unit are controlled based on the sensing result, as discussed above.

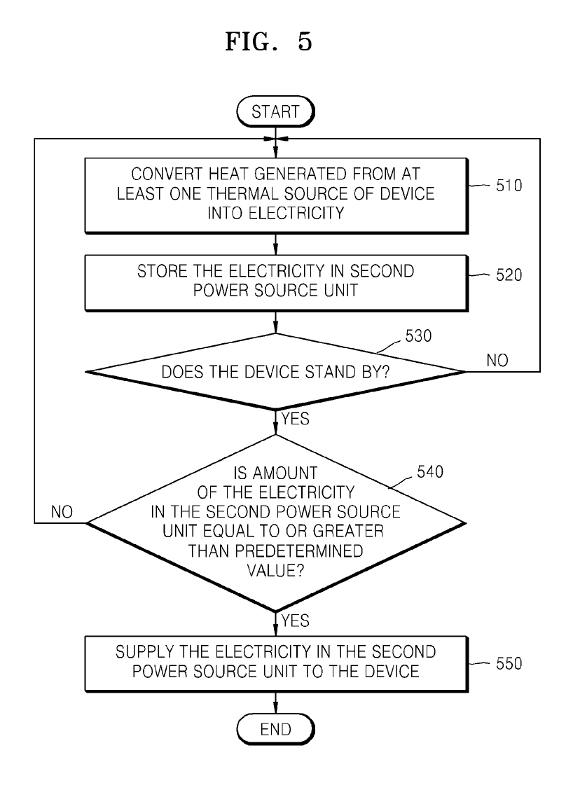

FIG. 5 is a flowchart illustrating an electric power supply method according to another embodiment of the present invention. In FIG. 5, the first power source unit and the second power source unit are controlled. In operation 510, an electric power supply apparatus (hereinafter referred to as “the apparatus”) converts heat generated from at least one electric power source of a device when the device operates using electricity from a first power source unit. Operation 510 corresponds to operation 410 illustrated in FIG. 4.

In operation 520, the apparatus stores the electricity, which was obtained through thermoelectric conversion in operation 510, in a second power source unit. Operation 520 corresponds to operation 420 illustrated in FIG. 4.

In operation 530, the apparatus determines whether the device is standing by, that is, whether the device is operating in the standby mode. If it is determined that the device is operating in the normal mode and not in the standby mode, operations 510 and 520 are performed again.

In operation 540, the apparatus determines whether the amount of the electricity stored in the second power source unit is equal to or greater than a predetermined value, i.e., whether the amount of the electricity is enough to operate the device in the standby mode. Even if it is determined in operation 530 that the device operates in the standby mode, when it is determined in operation 540 that the amount of the electricity in the second power source unit is less than the predetermined value, operations 510 and 520 are performed again in order to charge the second power source unit with electricity, for example, or to simply supply electricity from the first power source unit to the device.

On the other hand, if it is determined that the amount of the electricity in the second power source unit is equal to or greater than the predetermined value, the electricity in the second power source unit is supplied to the device. The electricity in the second power source unit is supplied to the device only when both the device operates in the standby mode and the amount of the electricity in the second power source unit is equal to or greater than the predetermined value.

The system according to aspects of the present invention can be embodied as computer readable code in a computer readable recording medium. Here, the computer readable medium may be any recording apparatus capable of storing data that is read by a computer system, e.g., a read-only memory (ROM), a random access memory (RAM), a compact disc (CD)-ROM, a magnetic tape, a floppy disk, an optical data storage device, and so on. The computer readable medium can be distributed among computer systems that are interconnected through a network, and the present invention may be stored and implemented as computer readable code in the distributed system.

In aspects of the present invention, the first power source unit 150 may be a secondary battery so that electricity that is stored therein is supplied to the device 140. If a secondary battery, the first power source unit 150 may be charged from an external power source. In aspects of the present invention, the electric power supply apparatus 100, the device 140, the first power source 150, and the second power source 160 may be portions of a television (TV), a digital versatile disc (DVD) player that read data from a DVD, or a portable electronic device, such as, a portable computer, a laptop computer, a portable audio/video devices, PDAs, a cell phone, or similar devices.

As described above, according to the above aspects of the present invention, it is possible to minimize consumption of power in a device by converting thermal energy generated when the device operates using external electric power into electric energy, storing the electric energy, and operating the device using the stored electric energy when external power is not used.

Although a few aspects of the present invention have been shown and described, it would be appreciated by those skilled in the art that changes may be made in the aspects without departing from the principles and spirit of the invention, the scope of which is defined in the claims and their equivalents.

What is claimed is:

1. An electric power supply apparatus usable with a device, and to control supply of electricity from first and second power source units to the device, comprising:
a thermoelectric conversion unit to convert heat generated from at least one thermal source of the device into electricity when the device operates using electricity from the first power source unit;
a charging unit to charge the electricity obtained by the thermoelectric conversion unit to the second power source unit; and
a power control unit to control the first and second power source units in order to supply the electricity of the first or second power source unit to the device.

2. The electric power supply apparatus of claim 1, wherein if the device is switched to a standby mode, the power control unit controls the first and second power source units in order to supply the electricity of the second power source unit to the device.

3. The electric power supply apparatus of claim 2, wherein the power control unit controls the first and second power source units in order to supply the electricity of the second power source unit to the device if the amount of the electricity in the second power source unit is equal to or greater than a predetermined value.

4. The electric power supply apparatus of claim 2, wherein the power control unit controls the first and second power source units in order to supply the electricity from the first power source unit to the device if the amount of the electricity in the second power source unit is less than a predetermined value.

5. The electric power supply apparatus of claim 2, wherein the second power source unit comprises a rechargeable secondary battery.

6. The electric power supply apparatus of claim 2, wherein the thermoelectric conversion unit comprises a plurality of thermoelectric generators to convert heat generated from a plurality of thermal sources of the device into electricity.

7. The electric power supply apparatus of claim 6, wherein the charging unit comprises:
a blocking unit having a plurality of diodes respectively connected to the thermoelectric generators, the diodes blocking electricity generated by each of the thermoelectric generators from flowing towards the other thermoelectric generators; and
a battery charging unit to charge the second power source unit with the electricity generated by the thermoelectric generators.

8. The electric power supply apparatus of claim 6, wherein the charging unit comprises an electric conversion unit to convert electricity having different power levels, which are generated by the respective thermoelectric generators, into electricity having the same voltage.

9. The electric power supply apparatus of claim 6, wherein the power control unit comprises a sensing unit to sense whether the device is switched to the standby mode.

10. An electric power supply method of supplying electricity from first and second power source units to a device, comprising:
if the device operates using electricity from the first power source unit, converting heat generated from at least one thermal source of the device into electricity;
storing the converted electricity in the second power source unit; and
controlling the first and second power source units in order to supply the electricity of the first or second power source unit to the device.

11. The electric power supply method of claim 10, wherein the controlling of the first and second power source units comprises:
sensing whether the device is switched to a standby mode; and
controlling the first and second power source units in order to supply the electricity of the first or second power source unit to the device, based on the sensing result.

12. The electric power supply method of claim 11, wherein if the device is switched to the standby mode, the controlling of the first and second power source units comprises controlling the first and second power source units in order to supply the electricity of the second power source unit to the device.

13. The electric power supply method of claim 12, wherein the controlling of the first and second power source units comprises controlling the first and second power source units in order to supply the electricity of the second power source unit to the device if the amount of the electricity in the second power source unit is equal to or greater than a predetermined value.

14. The electric power supply method of claim 12, wherein the controlling of the first and second power source units comprises controlling the first and second power source units in order to supply the electricity of the first power source unit to the device if the amount of the electricity in the second power source unit is less than a predetermined value.

15. The electric power supply method of claim 11, wherein the second power source unit comprises a rechargeable secondary battery.

16. The electric power supply method of claim 10, wherein the converting of the heat generated from the at least one thermal source of the device into electricity comprises converting the heat generated from a plurality of thermal sources of the device into electricity by using a plurality of thermoelectric generators.

17. The electric power supply method of claim 10, wherein the storing of the converted electricity in the second power source unit comprises:
converting electricity having different power levels, which are generated by respective ones of a plurality of thermoelectric generators, into electricity having the same voltage; and
charging the converted electricity having the same voltage to the second power source unit.

18. A computer readable recording medium having recorded thereon a computer program for an electric power supply apparatus to execute the method of claim 10 to supply electricity from a plurality of sources to a device.

19. An electronic apparatus having components that generate heat during operation thereof, the electronic apparatus comprising:
a first electric power source to supply main electric power to the electronic apparatus to operate the electronic apparatus in a normal mode;
a second electric power source to supply auxiliary electric power to the electronic apparatus in a standby mode, the auxiliary electric power being less than the main electric power;
an electric power supply apparatus to recycle thermal energy of the heat generated by at least one of the components into electricity during the normal mode, charge the electricity to the second electric power source during the normal mode, and control the second electric power source to supply the charged electricity as the auxiliary electric power to the electronic apparatus during the standby mode.

20. The electronic apparatus of claim 19, wherein the electric power supply apparatus includes a blocker to cause the electricity generated from the thermal energy to only flow to the second electric power source.

21. The electronic apparatus of claim 19, wherein,
the electric power supply apparatus selectively recycles the thermal energy into electricity when the thermal energy is at or greater than a designated level, and
the electric power supply apparatus selectively controls the second electric power source to supply the auxiliary electric power only when electric power of the second power source is at or greater than a designated level and the electronic apparatus is in the standby mode.

22. A method of supplying electric power to an electronic apparatus having components that generate heat during operation thereof, the method comprising:
supplying main electric power from a first electric power source to the electronic apparatus to operate the electronic apparatus in a normal mode;
recycling thermal energy of the heat generated by at least one of the components into electricity during the normal mode;
charging the electricity to the second electric power source during the normal mode; and
controlling a second electric power source to supply the charged electricity as auxiliary electric power to the electronic apparatus during the standby mode, the auxiliary electric power being less than the main electric power.

23. The method of claim 22, further comprising causing the electricity generated from the thermal energy to only flow to the second electric power source.

24. The method of claim 22, wherein,
the recycling of the thermal energy into electricity is selectively performed when the thermal energy is at or greater than a designated level, and
the controlling of the second electric power source to supply the auxiliary electric power is selectively performed only when electric power of the second power source is at or greater than a designated level and the electronic apparatus is in the standby mode.
